(19) United States
(12) Patent Application Publication
(10) Pub. No.: US 2024/0234195 A9
(43) Pub. Date: Jul. 11, 2024

(54) Semiconductor Device and Method of Making a Substrate with Improved Substrate Mounting Apparatus

(71) Applicant: UTAC Headquarters Pte. Ltd., Singapore (SG)

(72) Inventors: Hua Hong Tan, Singapore (SG); Chee Kay Chow, Singapore (SG); Zong Xiang Cai, Dongguan (CN); Wei Ming Xian, Dongguan (CN); Yao Hong Wu, Dongguan (CN); Wing Keung Lam, Dongguan (CN)

(73) Assignee: UTAC Headquarters Pte. Ltd., Singapore (SG)

(21) Appl. No.: 18/490,741

(22) Filed: Oct. 19, 2023

Related U.S. Application Data
(60) Provisional application No. 63/380,244, filed on Oct. 20, 2022.

(51) Int. Cl. H01L 21/683; H01L 21/48; H01L 21/67; H01L 21/677

(52) U.S. Cl. CPC H01L 21/6838; H01L 21/4867; H01L 21/6715; H01L 21/67259; H01L 21/67736; H01L 21/67742; H01L 21/67766

(57) ABSTRACT

A manufacturing system includes a substrate disposed on a conveyer system. The conveyer system includes a pair of side supports. The substrate is moved on the conveyer system until the substrate is disposed over a bottom support block. The bottom support block is raised to physically contact the substrate. A transfer arm module is provided. The transfer arm module includes a flat bottom surface and an opening formed in the flat bottom surface. The transfer arm module is disposed with the flat bottom surface physically contacting the substrate opposite the bottom support block. A vacuum is enabled through the opening of the transfer arm module. The substrate is lifted off the bottom support block using the vacuum. The substrate is moved over a printing pallet using the transfer arm module. The vacuum is disabled when the substrate is in a positioning area of the printing pallet.

### CLAIM OF DOMESTIC PRIORITY

The present application claims the benefit of U.S. Provisional Application No. 63/380,244, filed Oct. 20, 2022, which application is incorporated herein by reference.

### FIELD OF THE INVENTION

The present invention relates in general to semiconductor devices and, more particularly, to a semiconductor device and method of making a substrate with an improved substrate mounting apparatus.

### BACKGROUND OF THE INVENTION

Semiconductor devices are commonly found in modern electronic products. Semiconductor devices perform a wide range of functions, such as signal processing, high-speed calculations, sensors, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices are commonly formed by mounting one or more semiconductor die and other electrical components onto a substrate. Substrates are transported through the substrate manufacturing process on a conveyer system. FIG. 1 shows an exemplary substrate 10 in the manufacturing process. Substrate 10 includes one or more insulating layers 12 and one or more conductive layers 14 interleaved between or over surfaces of the insulating layers. Conductive layers 14 include vertically oriented conductive vias to connect the layers to each other. Insulating layer 12 is a core insulating board in one embodiment, with conductive layers 14 patterned over the top and bottom surfaces, e.g., a copper-clad laminate substrate. Any suitable type of package substrate is used for substrate 10 in other embodiments.

In the conveyer system, substrate 10 is supported by two lateral parallel side supports 20a and 20b. Especially for thin substrates 10, there is a tendency for the substrate to be deformed or warped from the prior processes. In addition, the substrates commonly sag between side supports 20a and 20b as shown in FIG. 1. These deformities create problems for subsequent manufacturing steps, such as screen printing, that adversely affect functionality and reliability when the substrate is eventually included in a semiconductor package. Therefore, a need exists for improved manufacturing methods and an improved substrate mounting apparatus.

### BRIEF DESCRIPTION OF THE DRAWINGS

FIG. 1 illustrates a semiconductor substrate sagging during processing;

FIGS. 2a and 2b illustrate a bottom support block;

FIGS. 3a-3c illustrate a transfer arm module;

FIGS. 4a-4c illustrate the transfer arm module picking a substrate from the bottom support block;

FIGS. 5a-5e illustrate a transfer arm module disposing the substrate in a printing pallet;

FIGS. 6a-6d illustrate alternative embodiments for the printing pallet;

FIGS. 7a-7f illustrate moving the substrate from the printing pallet to a base carrier using the transfer arm module;

FIG. 8 illustrates a system and method of using the substrate mounting apparatus; and

FIGS. 9a-9e illustrate forming a semiconductor package with the substrate.

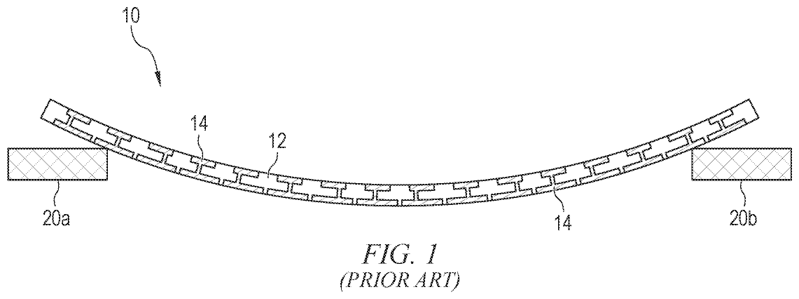

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

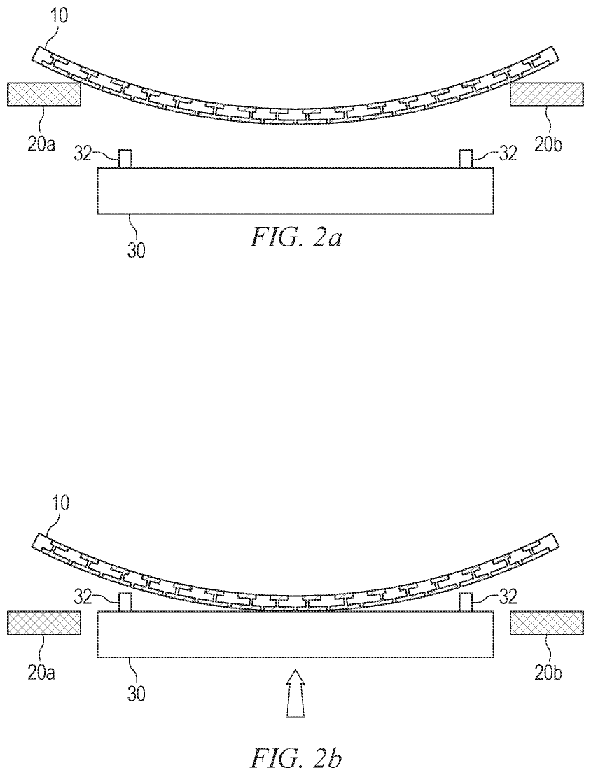

FIG. 2a shows the conveyer system with side supports 20a-20b and with the addition of a bottom support block 30. Bottom support block 30 stays at a static position under the conveyer and substrate 10 is transferred laterally to above the bottom support block by the conveyer system 20. Bottom support block 30 can be actuated up and down (raised and lowered) and is shown in the lowered position in FIG. 2a. In FIG. 2b, once substrate 10 is located over bottom support block 30, the bottom support block is raised so that the top surface of the bottom support block is approximately even with, or slightly higher than, the tops of side supports 20a-20b.

Bottom support block 30 has optional locating pins or sensors 32 on the top surface of the bottom support block. Locating sensors 32 can be pins that are pressed into bottom support block 30 to toggle embedded switches, optical or sonic sensors, hall effect sensors, or another suitable type of sensor able to detect the presence of a substrate 10 on bottom support block 30. When substrate 10 is laying flat on bottom support block 30, and positioned properly, the one or more locating sensors 32 are triggered and the electrical control systems proceed knowing that the substrate is in the proper position.

The previous sagging of substrate 10 between side supports 20 imparted a curvature to the substrate, resulting in the substrate bending upwards away from bottom support block 30 and therefore failing to trigger locating sensors 32. The curvature illustrated in FIG. 2b is exaggerated, and in practice the warpage and curve of substrate 10 may or may not prevent the triggering of locating sensors 32. In any case, even minor warpage can result in errors in the following manufacturing processes that reduce yield.

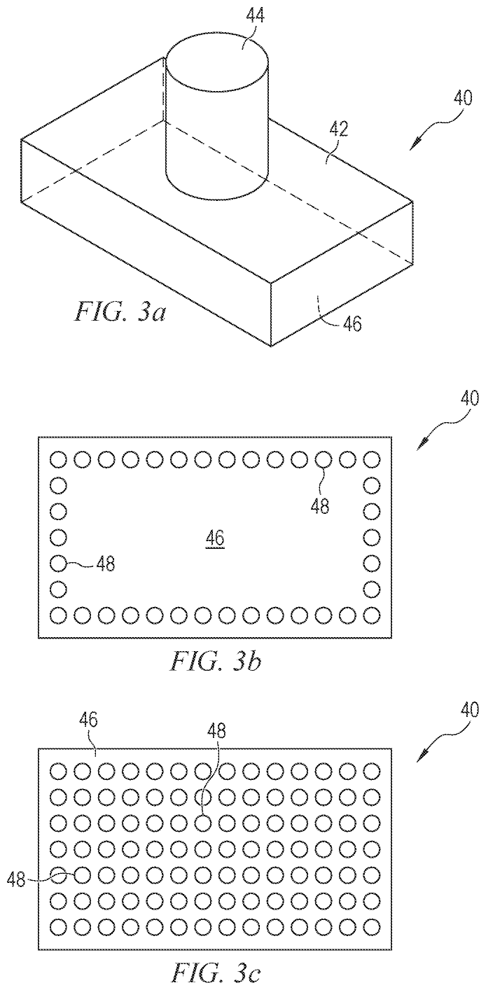

FIGS. 3a-3c illustrate a transfer arm module 40 that can be used to pick up substrate 10 off of bottom support block 30 and counteract warpage. Transfer arm module 40 includes a pickup head 42 and a transfer arm 44. Pickup head 42 includes a flat bottom surface 46 with apertures or openings 48 formed in the bottom surface. Apertures 48 allow a vacuum or reduced air pressure applied through transfer arm 44 to reduce air pressure at bottom surface 46. FIG. 3b shows an embodiment where apertures 48 are formed around the perimeter of bottom surface 46. FIG. 3c illustrates another embodiment where apertures 48 are spread across an entirety of bottom surface 48. Other patterns are used in other embodiments.

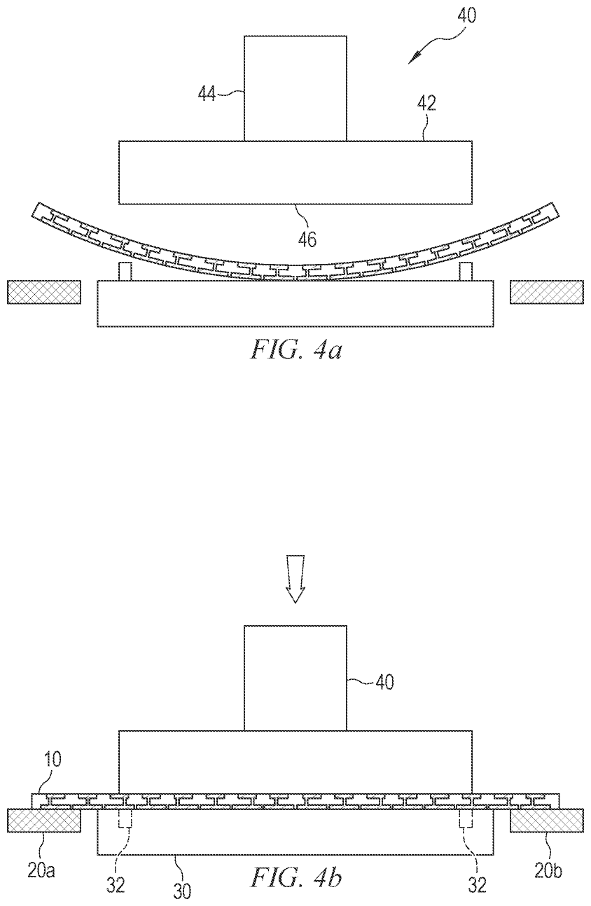

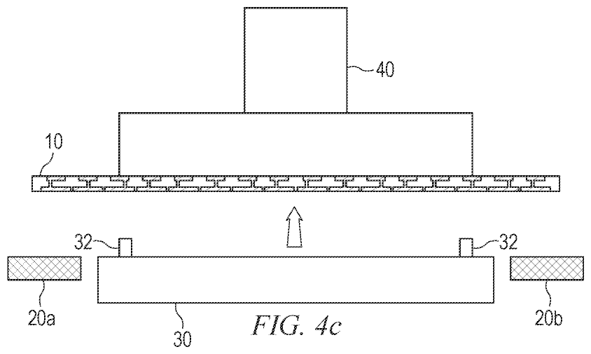

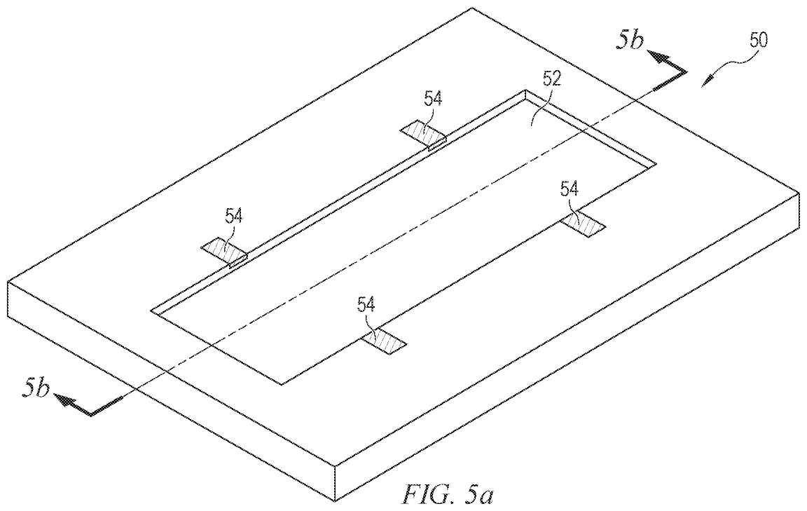

FIGS. 4a-4c illustrate picking up substrate 10 from bottom support block 30 using transfer arm module 40. In FIG. 4a, transfer arm module 40 is moved over substrate 10 on bottom support block 30 using a robot arm or other actuating system. Bottom surface 46 is oriented toward substrate 10 and parallel to the top surface of bottom support block 30.

In FIG. 4b, transfer arm module 40 is pressed down onto bottom support block 30 and flattens substrate 10 between the transfer arm module and bottom support block. Any significant warpage or curvature of substrate 10 is substantially flattened out by the pressure of two flat surfaces, i.e., the inner-facing surfaces of transfer arm module 40 and bottom support block 30, on opposite sides of the substrate pressing on the substrate. Locating sensors 32 are pins that are pressed into bottom support block 30 by the flattening of substrate 10, thereby confirming the proper location of the substrate.

A vacuum is applied through transfer arm 44 and pickup head 42 to apertures 48 on bottom surface 46 to create a suction force on substrate 10. The vacuum is turned on when transfer arm module 40 presses substrate 10 flat against bottom support block 30 and locating sensors 32 are triggered, indicating that the substrate is positioned properly. When locating sensors 32 are not used, the vacuum is enabled based on the timing of movements of system components. When transfer arm module 40 is raised in FIG. 4c, the vacuum through transfer arm module 40 continues to apply an upward force on substrate 10 to pick up the substrate and maintain the substrate in a substantially flat state against bottom surface 46.

Even though significant warpage or curvature was imparted on substrate 10 previously in the manufacturing process, picking up the substrate using bottom support block 30 and transfer arm module 40 allows the substrate to be flattened and maintained in a flat state during transfer. Transfer arm module 40 moves substrate 10 from a first position to a second position while the suction force holding the substrate against bottom surface 46 reduces the likelihood of further deformation occurring. After transfer arm module 40 lifts a first substrate 10 off of bottom support block 30, the bottom support block is moved down again as shown in FIG. 2a to allow another sagging substrate 10 to move along conveyer system 20 and be received over the bottom support block.

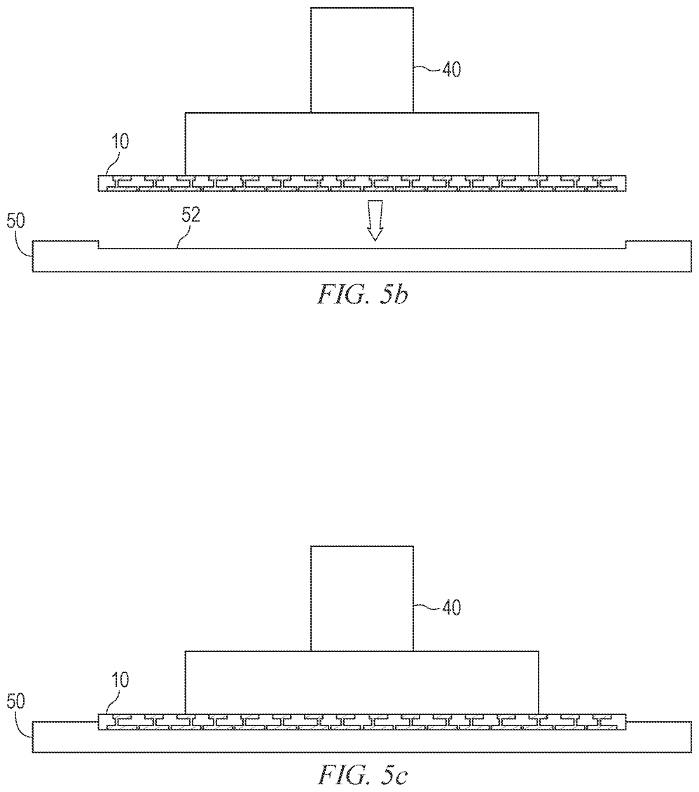

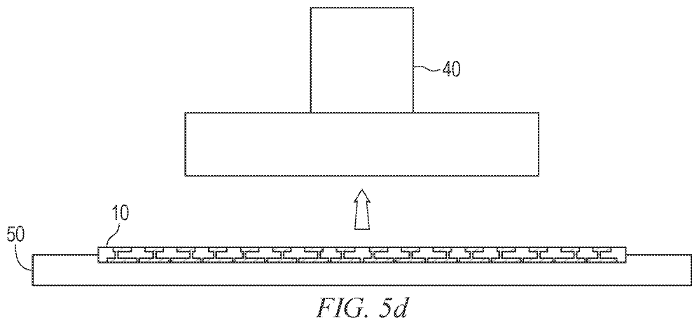

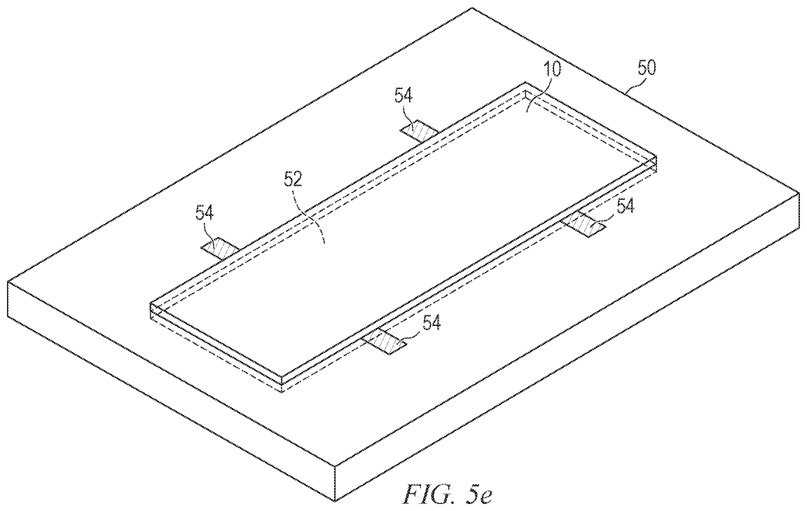

FIGS. 5a-5e illustrate a printing pallet 50 usable to hold substrate 10 flat during a screen-printing process. FIG. 5a shows a perspective view of a printing pallet 50. Printing pallet 50 is a substantially flat sheet of material, e.g., metal or plastic, with an optional recessed substrate positioning area 52 centrally located. A depth of positioning area 52 is less than a height of substrate 10 so that a top surface of the substrate extends out of the recess of positioning area 52, above or proud of the top surface of printing pallet 50, when the substrate is placed therein.

A plurality of tabs or clips 54 is positioned around positioning area 52. Clips 54 are configured to hold onto the edges of substrate 10 while the substrate is on printing pallet 50 so that the substrate edges do not curl back up during the screen-printing process. Clips 54 can be spring loaded to apply a pressure to the edges of substrate 10, or static clips that simply extend into the footprint of positioning area 52 to apply pressure against the substrate. Clips 54 may also be configured to fold up and down onto a part of substrate 10 that does not need to be screen printed.

FIG. 5b shows a cross-sectional view of transfer arm module 40 placing substrate 10 onto printing pallet 50. After picking up substrate 10 in FIG. 4c, transfer arm module 40 is moved from over bottom support block 30 to over printing pallet 50 such that the footprint of substrate 10 is completely within the footprint of positioning area 52. Transfer arm module 40 is lowered to place substrate 10 within the recess of positioning area 52. FIG. 5c illustrates substrate 10 having been lowered. Clips 54 engage with the edges of substrate 10 to keep the substrate substantially flat. The footprint of positioning area 52 is substantially identical to the footprint of substrate 10, except the positioning area is slightly larger to allow the substrate to be inserted without substantial friction.

The vacuum of transfer arm module 40 is disabled and the transfer arm module is moved away from printing pallet 50 in FIG. 5d without lifting substrate 10 off of the printing pallet. FIG. 5e shows a perspective view of substrate 10 on printing pallet 50 after transfer arm module 40 has been moved away. For convenience of screen printing, the depth of positioning area 52 is such that when substrate 10 is provided in the positioning area, the substrate top surface is raised from the printing pallet top surface. Substrate 10 can now be screen printed after having been flattened by bottom support block 30 and transfer arm module 50 and while being held flat by printing pallet 50. Screen-printing occurs without error due to the physical corrections made to reduce warpage or curvature of substrate 10.

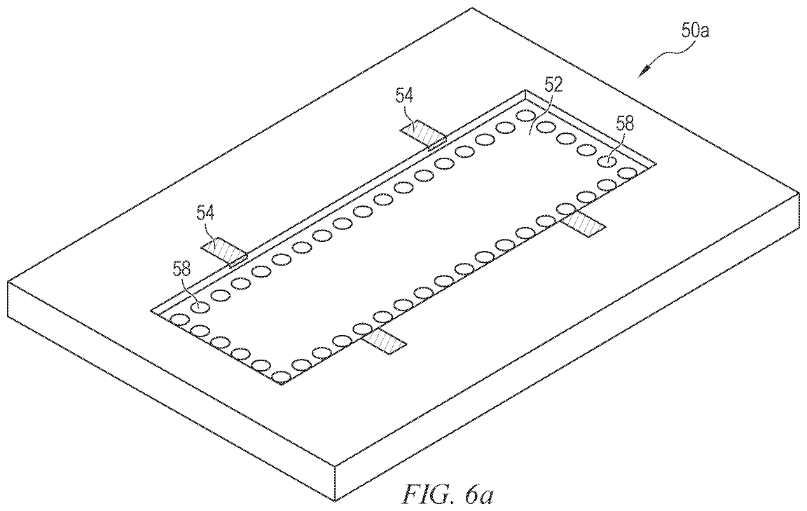

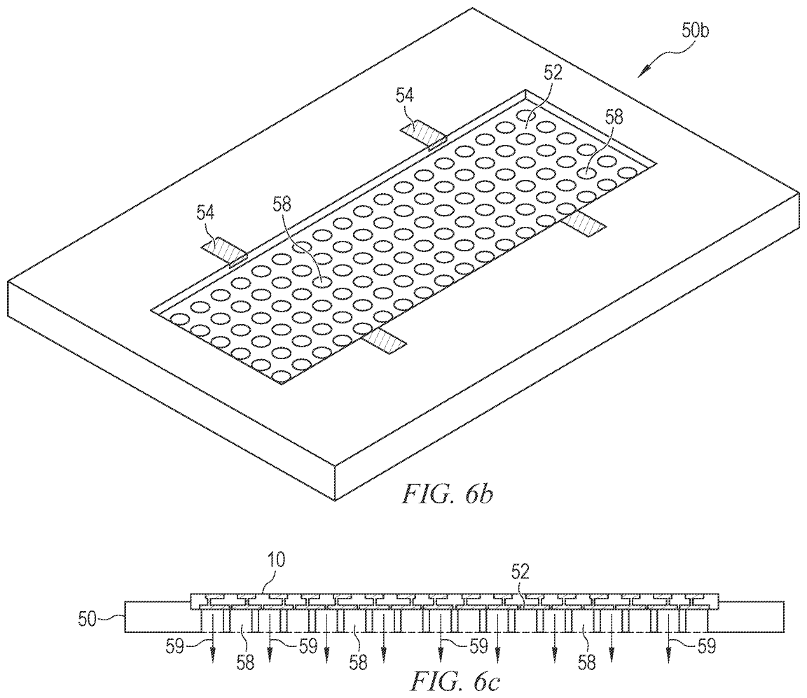

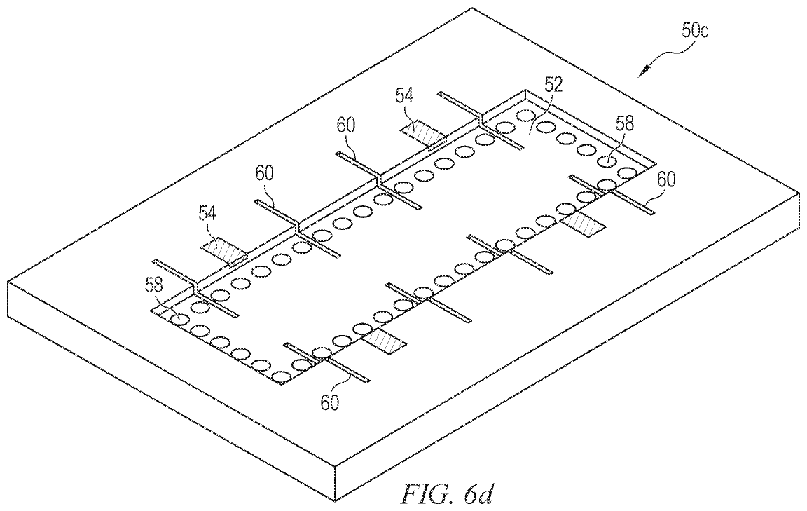

FIGS. 6a-6c show alternative printing pallet embodiments. In FIG. 6a, printing pallet 50a is similar to printing pallet 50 above with the addition of openings or apertures 58 within positioning area 52. Apertures 58 are formed around a perimeter of positioning area 52, where they will be located under the edges of a substrate 10 disposed in the positioning area, because the edges of a substrate curling up is the biggest issue being addressed. However, FIG. 6b shows another embodiment as printing pallet 50b having apertures 58 distributed across an entire footprint of positioning area 52. Apertures 58 can be formed in any suitable pattern.

FIG. 6c shows a cross-sectional view with openings 58 extending into or through printing pallet 50a or 50b. Similar to apertures 48 of transfer arm module 40, apertures 58 are interconnected with each other and to a vacuum apparatus for applying a suction force to the bottom of a substrate 10 placed within positioning area 52. Apertures 58 can be connected to each other within printing pallet 50 or by a separate underlying vacuum component. Suction force applied by a vacuum generator through apertures 58, as indicated by arrows 59, can be used in addition to or instead of clips 54 to keep substrate 10 flat during the screen-printing process.

In FIG. 6d, printing pallet 50c includes vacuum release channels 60 formed from within positioning area 52 to outside of positioning area 52. Release channels 60 are cut or etched into printing pallet 50c and routed to ensure that desired areas of a substrate being processed are not subject to vacuum pressure. Release channels 60 can be oriented perpendicularly, interconnected with each other, two-dimensional shapes instead of linear, or any other suitable shape. Areas of a substrate 10 over a release channel 60 are not subject to vacuum because the release channel 60 allows in air from outside of positioning area 52. Release channels 60 can be used with the aperture 58 pattern of printing pallet 50a or 50b, or any other suitable aperture pattern.

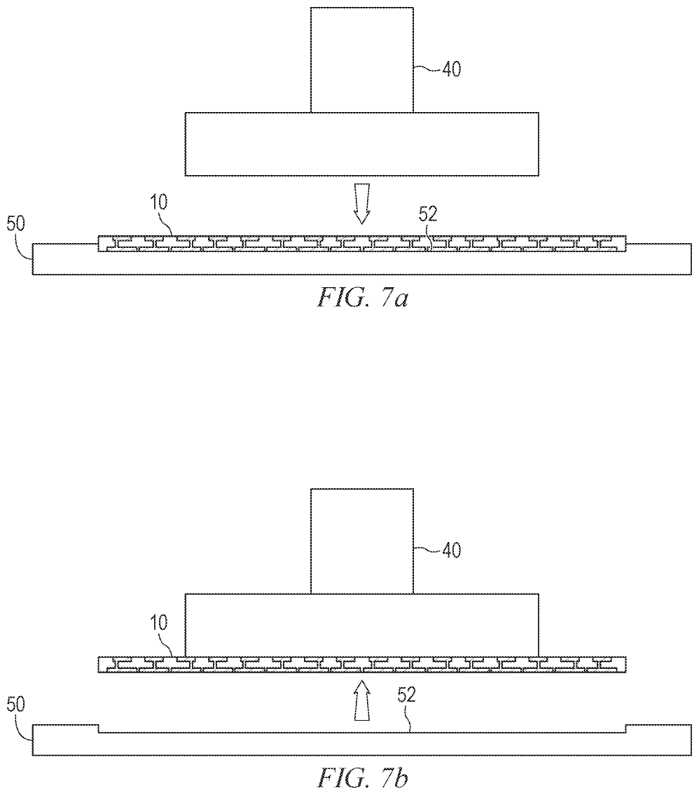

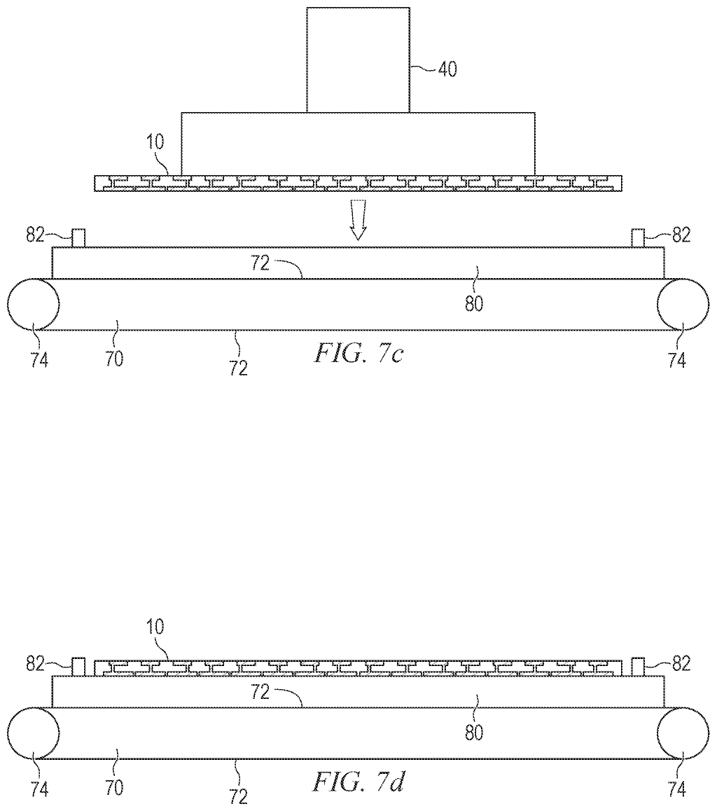

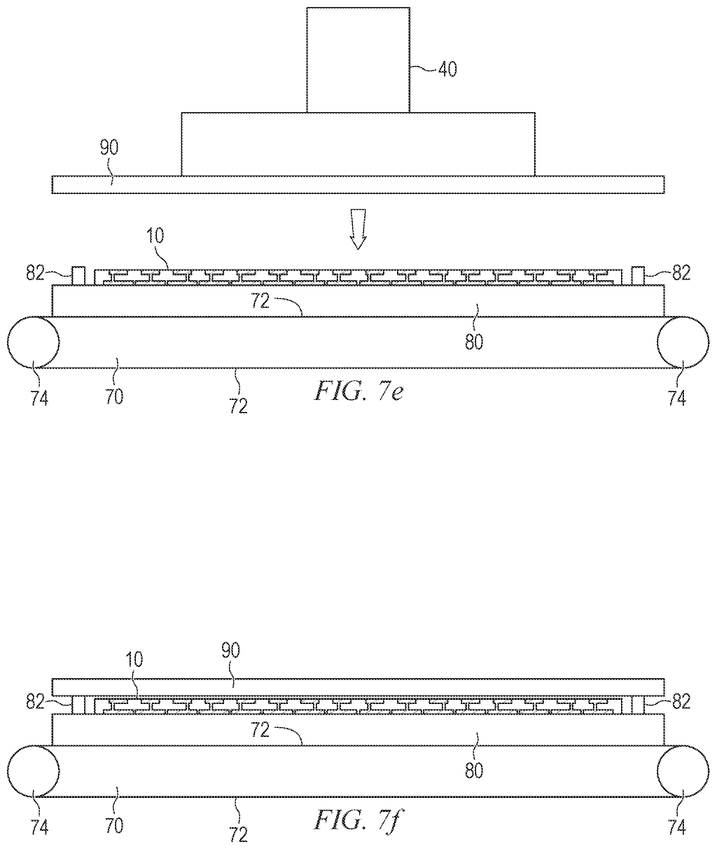

FIGS. 7a-7f illustrate moving substrate 10 from printing pallet 50 to a base carrier after completion of the screen-printing process. In FIG. 7a, transfer arm module 40 is moved back over printing pallet 50 with substrate 10. Printing pallet 50 may also be moved out of the screen printing machine prior to substrate 10 being picked up. The transfer arm module 40 used to remove substrate 10 from printing pallet 50 can be the same transfer arm used to load the substrate, or a different transfer arm can be used. Transfer arm module 40 is lowered onto substrate 10 and the vacuum is enabled to create suction force on the substrate to the transfer arm module.

Substrate 10 is lifted using transfer arm module 40 in FIG. 7b. If used, the vacuum applied to the bottom of substrate 10 through apertures 58 is disabled prior to lifting the substrate. By actuating transfer arm module 40 upward while the vacuum is enabled onto the top surface of substrate 10 through apertures 48, enough upward force is applied to substrate 10 to overcome the force of clips 54. Alternatively, clips 54 can be disengaged prior to lifting substrate 10.

FIG. 7c shows a conveyer system 70. Conveyer system 70 includes a belt 72 routed around two or more rollers 74. At least one roller 74 is attached to a motor to actuate the rollers to turn. The turning of rollers 74 moves belt 72 around the rollers. The top portion of belt 72 moves linearly between rollers 74 as the belt moves between the rollers. Belt 72 can be a metal, polymer, or other material with either a single continuous piece of material or multiple pieces of material flexibly interconnected with each other. Other types of conveyer systems are used in other embodiments.

A base carrier 80 is disposed on conveyer system 70. Base carrier 80 is made of metal, glass, plastic, or another similar rigid material to physically support a substrate 10 being stored on the base carrier. Base carrier 80 has vertical supports 82 disposed around the base carrier near a perimeter of the base carrier. Vertical supports 82 are positioned outside the footprint of where substrate 10 will be placed and have a height greater than a thickness of the substrate. Vertical supports 82 can be formed of metal and be threaded to screw into base carrier 80. Vertical supports 82 can alternatively be press fit, snapped, glued, or otherwise fastened to base carrier 80 or formed as an integral part of the base carrier. Any number of vertical supports 82 sufficient to support a cover can be used, e.g., one vertical support 82 at each corner of base carrier 80 or additional vertical supports along the edges of the base carrier. In another embodiment, vertical support 82 extends continuously all the way around the edges of base carrier 80.

In FIG. 7c, substrate 10 is moved over base carrier 80 on conveyer system 70 using transfer arm module 40. When substrate 10 is aligned properly to base carrier 80, transfer arm module 40 is lowered until substrate 10 is physically contacting the base carrier. The vacuum system of transfer arm module 40 is disabled to remove the force keeping substrate 10 attached to the transfer arm module, and the transfer arm module is moved away leaving the substrate on the base carrier on conveyer system 70 as shown in FIG. 7d.

In FIG. 7e, a top cover 90 is picked up by transfer arm module 40 using the force of a vacuum applied through apertures 48 and moved over base carrier 80 and substrate 10. Top cover 90 is a rigid sheet of material, e.g., glass, metal, acrylic, polymer, or another suitable material. Transfer arm module 40 picks up top cover 90 out of a top cover supply bin with a plurality of top covers stacked or otherwise organized in a manner to allow the transfer arm module to easily pick up a single top cover. Transfer arm module 40 used to install top cover 90 can be the same or a different transfer arm from those previously used.

Top cover 90 is lowered and mounted onto base carrier 80 via vertical supports 82 in FIG. 7f. The vacuum applied through transfer arm module 40 is disabled to allow the transfer arm module to be moved elsewhere while leaving top cover 90 on base carrier 80. Top cover 90 may simply rest on vertical supports 82 over substrate 10. In other embodiments, top cover 90 is attached to vertical supports 82 by screws, snaps, magnets, adhesive, or another type of fastener. Top cover 90 is oriented parallel to and slightly separated from substrate 10. In some embodiments, vertical supports 82 form a continuous wall around substrate 10 to fully enclose the substrate within base carrier 80. With top cover 90 installed, conveyer system 70 transfers substrate 10 enclosed within base carrier 80 out of the carrier module and to a storage module for completed substrates.

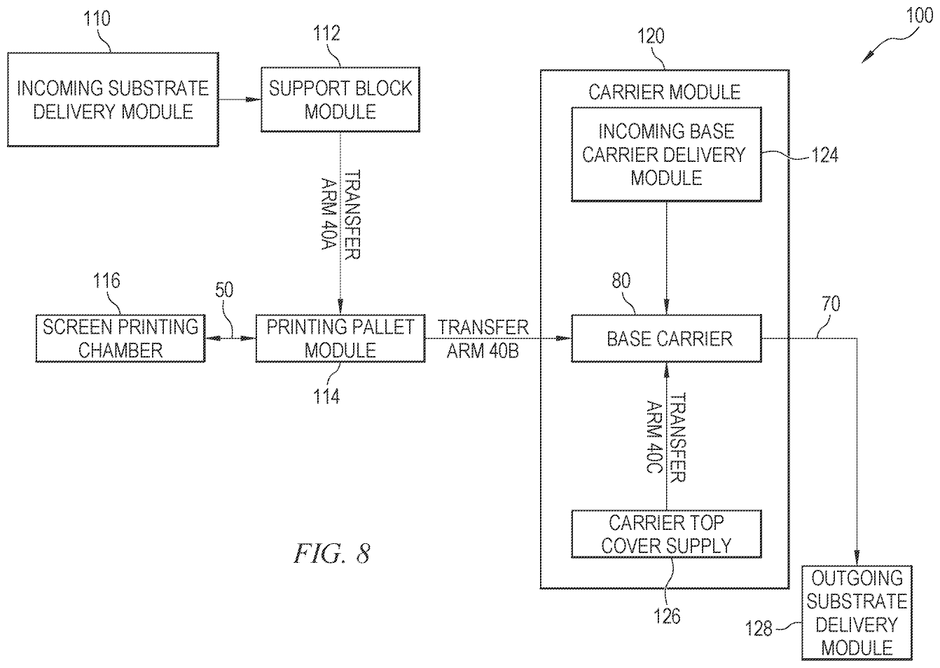

FIG. 8 illustrates a manufacturing system 100 that combines the above-described bottom support block 30, transfer arm module 40, printing pallet 50, and base carrier 80 to manufacture a substrate 10. System 100 includes an incoming substrate delivery module 110 to deliver a substrate 10 over a support block module 30 at or within support block module 112. Incoming substrate delivery module 110 includes, e.g., a conveyer system with side supports 20a and 20b. Incoming substrate delivery module 110 can also include a pick and place machine or any other suitable system for repeatedly disposing a series of substrates 10 over bottom support block 30.

Support block module 112 includes a bottom support block 30 and an actuation mechanism to raise and lower the bottom support block. The actuation mechanism can include computer-controlled stepper motors, hydraulic actuators, or any other suitable means of raising and lowering bottom support block 30. A first transfer arm module 40a is used to transfer the substrate 10 from support block module 112 to printing pallet module 114. Transfer arm module 40a can be part of a standalone transfer arm module or integrated as part of support block module 112 or printing pallet module 114.

Printing pallet module 114 includes one or more printing pallets 50 and a means to transfer a printing pallet with a substrate 10 into screen printing chamber 116. Printing pallet module 114 moves a printing pallet 50 loaded with a substrate 10 into screen printing chamber 116 for screen printing, and then removes the printing pallet and substrate from the screen printing chamber after processing is completed. In other embodiments, printing pallets 50 are used for other processing steps, e.g., formation of conductive or insulating layers, etching, cleaning, or backgrinding. Screen printing is only one exemplary process step for substrate 10. Any suitable processing can be performed on substrate 10 while held by printing pallet 50 instead of or in addition to screen printing. The benefits of system 100 in reducing warpage apply to essentially any processing step performed on substrate 10. Any other type of carrier can be used as appropriate, with or without clips 54 or apertures 58, to perform other types of processing besides screen printing.

After printing pallet module 114 removes the printing pallet 50 with substrate 10 from screen printing chamber 116, a second transfer arm module 40b moves the substrate 10 from printing pallet 50 to a base carrier 80 in carrier module 120. Separate transfer arms 40a and 40b allow pipelining where transfer arm 40a disposes a second substrate on printing pallet 50 as soon as the transfer arm 40b removes the first substrate, thus increasing efficiency of system 100. In other embodiments, a single transfer arm 40 is used for both purposes.

Carrier module 120 includes an incoming base carrier delivery module 124 to deliver a new base carrier 80 for each incoming substrate 10 delivered by transfer arm module 40b. Base carrier delivery module 124 includes a storage means with a plurality of base carriers 80 configured to be dispensed or picked up one at a time, e.g., a stack or tape reel. An individual base carrier 80 can be picked and placed from the storage means, or the storage means can include a dispenser mechanism for dispensing a single base carrier onto conveyer system 70. In some embodiments, a transfer arm module 40 is used to move a base carrier 80 from incoming base carrier delivery module 124 to conveyer system 70.

A carrier top cover supply 126 includes a plurality of top covers 90. Top covers 90 are stored in a stack or another suitable means that allows transfer arm module 40c to pick up individual top covers and mount one of the top covers onto each base carrier 80 placed within carrier module 120 by transfer arm module 40b. Once a top cover 90 is mounted onto a base carrier 80 over a substrate 10, conveyer system 70 moves the base carrier into outgoing substrate delivery module 128 and manufacturing continues by adding another top cover onto the next base carrier with the next substrate.

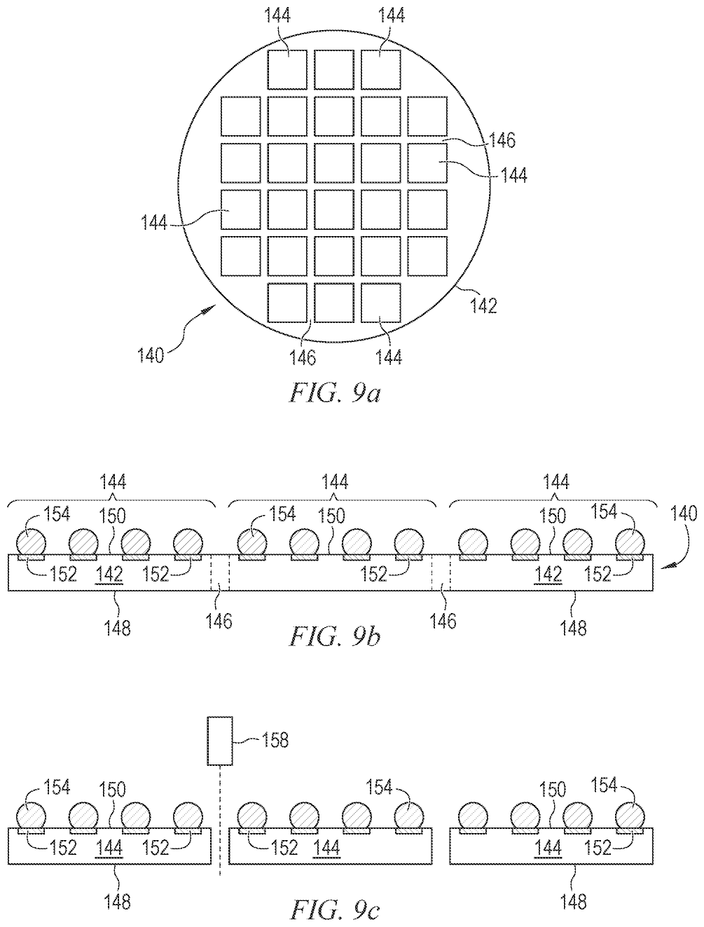

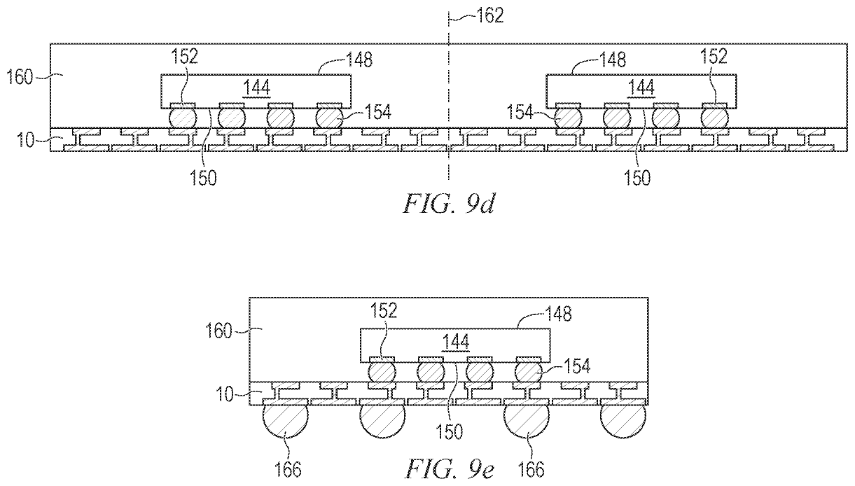

Outgoing substrate delivery module 128 stores the base carriers as a stack or in another suitable form for later usage of the substrates. Substrates 10 are used by a semiconductor package manufacturing company to form semiconductor packages. FIGS. 9a-9e illustrate one exemplary process for forming a semiconductor package with substrate 10.

FIG. 9a shows semiconductor wafer or substrate 140 with a base substrate material 142, such as silicon (Si), silicon carbide (SiC), cubic silicon carbide (3C—SiC), germanium, aluminum phosphide, aluminum arsenide, gallium arsenide, gallium nitride, indium phosphide, diamond, and all families of III-V and II-VI semiconductor materials for structural support. A plurality of semiconductor die or components 144 is formed on wafer 140 separated by a non-active, inter-die wafer area or saw street 146. Saw street 146 provides cutting areas to singulate semiconductor wafer 140 into individual semiconductor die 144. In one embodiment, semiconductor wafer 140 has a width or diameter of 100-450 millimeters (mm).

FIG. 9b shows a cross-sectional view of a portion of semiconductor wafer 140. Each semiconductor die 144 has a back or non-active surface 148 and an active surface 150 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 150 to implement analog circuits or digital circuits, such as digital signal processor (DSP), application specific integrated circuits (ASIC), memory, or other signal processing circuit.

Semiconductor die 144 may also contain IPDs, such as diodes, inductors, capacitors, and resistors, for RF signal processing.

An electrically conductive layer 152 is formed over active surface 150 using PVD, CVD, electrolytic plating, electroless plating process, or other suitable metal deposition process. Conductive layer 152 can be one or more layers of aluminum (Al), copper (Cu), tin (Sn), nickel (Ni), gold (Au), silver (Ag), or other suitable electrically conductive material. Conductive layer 152 operates as contact pads electrically connected to the circuits on active surface 150.

An electrically conductive bump material is deposited over conductive layer 152 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 152 using a suitable attachment or bonding process. In one embodiment, the bump material is reflowed by heating the material above its melting point to form balls or bumps 154. In one embodiment, bump 154 is formed over an under-bump metallization (UBM) having a wetting layer, barrier layer, and adhesion layer. Bump 154 can also be compression bonded or thermocompression bonded to conductive layer 152. Bump 154 represents one type of interconnect structure that can be formed over conductive layer 152. The interconnect structure can also use bond wires, conductive paste, stud bump, micro bump, or other electrical interconnect.

In FIG. 9c, semiconductor wafer 140 is singulated through saw street 146 using a saw blade or laser cutting tool 158 into individual semiconductor die 144. The individual semiconductor die 144 can be inspected and electrically tested for identification of known good die (KGD) post singulation.

In FIG. 9d, a panel of semiconductor packages is formed on substrate 10 by mounting semiconductor die 144 onto the substrate. Semiconductor die 144 are picked and placed onto substrate 10 with bumps 154 oriented toward the substrate. Bumps 154 are reflowed to mechanically and electrically connect semiconductor die 144 to substrate 10. Any other additional electrical components can be disposed on substrate 10 along with semiconductor die 144, e.g., additional die or discrete active or passive components, to form more complex semiconductor packages, e.g., system-in-package modules.

An encapsulant or molding compound 160 is deposited over and around substrate 10 and semiconductor die 144 using a paste printing, compressive molding, transfer molding, liquid encapsulant molding, vacuum lamination, spin coating, or other suitable applicator. Encapsulant 160 can be liquid or granular polymer composite material, such as epoxy resin, epoxy acrylate, or another suitable polymer, with or without a suitable filler. Encapsulant 160 is non-conductive, provides structural support, and environmentally protects the semiconductor device from external elements and contaminants.

In FIG. 9e, the panel of devices is singulated through saw street 162 using a saw blade or laser cutting tool into individual semiconductor packages 164. Bumps 166 are optionally formed on contact pads of substrate 10 for later mounting of package 164 onto the PCB or other substrate of a larger electrical device. Packages 164 are made with increased yield due to substrates 10 being manufactured more reliably using system 100. System 100 corrected existing deformation and avoided further deformation by properly supporting substrate 10 in a flat shape.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
disposing a substrate on a conveyer system including a pair of side supports;
moving the substrate on the conveyer system until the substrate is disposed over a bottom support block;
raising the bottom support block to physically contact the substrate;
providing a transfer arm module including a flat bottom surface and an opening formed in the flat bottom surface;
disposing the transfer arm module with the flat bottom surface physically contacting the substrate opposite the bottom support block;
enabling a vacuum through the opening of the transfer arm module;
lifting the substrate off of the bottom support block using the vacuum;
moving the substrate over a printing pallet using the transfer arm module; and
disabling the vacuum when the substrate is in a positioning area of the printing pallet.

2. The method of claim 1, further including screen printing the substrate while the substrate is disposed on the printing pallet.

3. The method of claim 1, further including:
providing the printing pallet to include a second opening formed in the positioning area; and
enabling a second vacuum through the second opening while the substrate is disposed on the printing pallet.

4. The method of claim 1, further including using a second transfer arm module to remove the substrate from the printing pallet and transfer the substrate to a base carrier.

5. The method of claim 4, further including using a third transfer arm module to dispose a top cover over the base carrier and substrate.

6. The method of claim 1, wherein the bottom support block includes a locating sensor.

7. A method of making a semiconductor device, comprising:
disposing a substrate over a bottom support block;
raising the bottom support block to physically contact the substrate;
providing a transfer arm module including a flat bottom surface and an opening formed in the flat bottom surface;
disposing the transfer arm module with the flat bottom surface physically contacting the substrate opposite the bottom support block;
enabling a vacuum through the opening of the transfer arm module; and
lifting the substrate off of the bottom support block using the vacuum.

8. The method of claim 7, further including moving the substrate over a carrier using the transfer arm module.

9. The method of claim 8, further including:
providing the carrier to include a second opening; and
enabling a second vacuum through the second opening while the substrate is disposed on the carrier.

10. The method of claim 8, further including using a second transfer arm module to transfer the substrate to a base carrier.

11. The method of claim 10, further including using a third transfer arm module to dispose a top cover over the base carrier and substrate.

12. The method of claim 8, further including performing a manufacturing process step on the substrate while the substrate is disposed on the carrier.

13. The method of claim 7, wherein the bottom support block includes a locating sensor.

14. A manufacturing system, comprising:
a bottom support block;
a transfer arm module disposed over the bottom support block, wherein the transfer arm module includes a flat bottom surface and an opening formed through the flat bottom surface; and
a vacuum generating device coupled to the opening of the transfer arm module.

15. The manufacturing system of claim 14, further including a printing pallet module comprising a printing pallet disposed adjacent to the transfer arm module.

16. The manufacturing system of claim 15, wherein the printing pallet includes a recessed positioning area.

17. The manufacturing system of claim 16, further including:
a second opening formed through the recessed positioning area; and
a second vacuum generating device coupled to the second opening.

18. The manufacturing system of claim 16, further including a substrate disposed in the recessed positioning area, wherein a depth of the recessed positioning area into the printing pallet is less than a thickness of the substrate.

19. The manufacturing system of claim 15, further including a base carrier delivery module disposed adjacent to the printing pallet module.

20. The manufacturing system of claim 14, wherein the bottom support block includes a locating sensor.
